(19) United States
(12) Patent Application Publication
(10) Pub. No.: US 2008/0305555 A1
(43) Pub. Date: Dec. 11, 2008

(54) Methods, Compositions and Devices For Performing Ionization Desorption on Silicon Derivatives

(75) Inventors: Edouard S. P. Bouvier, Stow, MA (US); Dennis DellaRovere, Mendon, MA (US); Christopher C. Benevides, Tiverton, RI (US); Keith Fadgen, Hope Valley, RI (US)

Correspondence Address: WATERS INVESTMENTS LIMITED;C/O WATERS CORPORATION, 34 MAPLE STREET - LG, MILFORD, MA, 01757, US

(73) Assignee: WATERS INVESTMENTS LIMITED, New Castle, DE (US)

(21) Appl. No.: 12/063,093

(22) PCT Filed: Aug. 16, 2006
(86) PCT No.: PCT/US06/31932

§ 371 Date: Jun. 20, 2008

Related U.S. Application Data
(60) Provisional application No. 60/708,985, filed on Aug. 17, 2005.

(51) Int. Cl. G01N 30/72; H01B 1/12; H01L 21/00

(52) U.S. Cl. 436/173; 252/500; 438/49; 257/E21.001

(57) ABSTRACT

A device for the presentation of samples for MALDI or DIOS ion source, comprising a semiconductor wafer body having at least one first surface and at least one second surface, the first surface being chemically modified to repel said aqueous sample toward said second surface.

### CROSS REFERENCE TO RELATED APPLICATIONS

This application claims benefit of U.S. Provisional Application No. 60/708,985, filed Aug. 17, 2005, (Attorney Docket No. WAF-399) the content of which is incorporated herein by reference.

### FIELD OF THE INVENTION

Embodiments of the present invention are directed to substrates for presenting a sample for desorption ionisation. These substrates are primarily used in laser equipped mass spectrometry instruments. Substrates of the present invention provide consistent results after repeated use.

### BACKGROUND OF THE INVENTION

Electrically conductive substrates are used with laser equipped mass spectrometers to perform analysis of samples. The substrate is usually in the form of a chip or plate having dimensions of approximately three to five centimetres long and wide and a thickness of approximately 0.5 to 5 millimetres. Sample, generally in the form of an aqueous solution, in which one or more substance is dissolved, is received on the substrate. In the case of matrix-assisted laser desorption ionization (MALDI) a radiation-adsorbing (or matrix) compound is also received on the substrate, to assist ionization. The substrate is placed in a holder in close proximity to the inlet of a mass spectrometer. A laser pulse is directed to the sample and a portion of the sample is ionized and vaporized from the surface of the substrate by the laser.

As used herein, the term “vaporized” means rendered into a gaseous state. The term “ionized” means having a positive or negative charge.

A further portion of the ionized sample is received by the mass analyzer, for example a time-of-flight (TOF) mass spectrometer. The mass spectrometer provides information as to the mass and charge of the ionized molecules that comprise the sample.

As used herein, the term “MALDI” refers to matrix assisted desorption ionization and the determination of mass and charge information of ions formed by laser ionisation. Such mass and charge information is typically in the form of a mass-to-charge ratio.

As used herein, the term “DIOS” refers to desorption ionization on silicon and the determination of mass and charge information of ions formed by laser ionization. Such mass and charge information is typically in the form of a mass to charge ratio.

Substrates are usually made from metals or metal alloys such as stainless steel. Such metal substrates are often coated with a hydrophobic polymer such as polytetrafluoroethylene (PTFE) to prevent aqueous sample from spreading out across the surface. Some substrates incorporate small, hydrophilic spots at points on the hydrophobic surface to aid the receiving of samples.

Metal substrates however can be expensive and difficult to manufacture, as significant machining is required to polish them to the necessary tolerances for MALDI analysis. The expense of metal substrates makes it undesirable to dispose of them after use, requiring analysts to spend valuable time cleaning substrates. Embodiments of the present invention provide a cheap and easily manufactured substrate, suitable as a single use product for MALDI analysis.

The term “aliphatic group” includes organic compounds characterized by straight or branched chains, typically having between 1 and 22 carbon atoms. Aliphatic groups include alkyl groups, alkenyl groups and alkynyl groups. In complex structures, the chains can be branched or cross-linked. Alkyl groups include saturated hydrocarbons having one or more carbon atoms, including straight-chain alkyl groups and branched-chain alkyl groups. Such hydrocarbon moieties may be substituted on one or more carbons with, for example, a halogen, a hydroxyl, a thiol, an amino, an alkoxy, an alkylcarboxy, an alkylthio, or a nitro group. Unless the number of carbons is otherwise specified, “lower aliphatic” as used herein means an aliphatic group, as defined above (e.g., lower alkyl, lower alkenyl, lower alkynyl), but having from one to six carbon atoms. Representative of such lower aliphatic groups, e.g., lower alkyl groups, are methyl, ethyl, n-propyl, isopropyl, 2-chloropropyl, n-butyl, sec-butyl, 2-aminobutyl, isobutyl, tert-butyl, 3-thiopentyl, and the like.

As used herein, the term “nitro” means —NO₂; the term “halogen” designates —F, —Cl, —Br or —I; the term “thiol” means SH; and the term “hydroxyl” means —OH.

The term “alicyclic group” includes closed ring structures of three or more carbon atoms. Alicyclic groups include cycloparaffins which are saturated cyclic hydrocarbons, cycloolefins and naphthalenes which are unsaturated with two or more double bonds, and cycloacetylenes which have a triple bond. They do not include aromatic groups. Examples of cycloparaffins include cyclopropane, cyclohexane, and cyclopentane. Examples of cycloolefins include cyclopentadiene and cyclooctatetraene. Alicyclic groups also include fused ring structures and substituted alicyclic groups such as alkyl substituted alicyclic groups. In the instance of the alicyclics such substituents can further comprise a lower alkyl, a lower alkenyl, a lower alkoxy, a lower alkylthio, a lower alkylamino, a lower alkylcarboxyl, a nitro, a hydroxyl, —CF₃, —CN, or the like.

The term “heterocyclic group” includes closed ring structures in which one or more of the atoms in the ring is an element other than carbon, for example, nitrogen, sulfur, or oxygen. Heterocyclic groups can be saturated or unsaturated and heterocyclic groups such as pyrrole and furan can have aromatic character. They include fused ring structures such as quinoline and isoquinoline. Other examples of heterocyclic groups include pyridine and purine. Heterocyclic groups can also be substituted at one or more constituent atoms with, for example, a halogen, a lower alkyl, a lower alkenyl, a lower alkoxy, a lower alkylthio, a lower alkylamino, a lower alkylcarboxyl, a nitro, a hydroxyl, —CF₃, —CN, or the like. Suitable heteroaromatic and heteroalicyclic groups generally will have 1 to 3 separate or fused rings with 3 to about 8 members per ring and one or more N, O or S atoms, e.g. coumarinyl, quinolinyl, pyridyl, pyrazinyl, pyrimidyl, furyl, pyrrolyl, thienyl, thiazolyl, oxazolyl, imidazolyl, indolyl, benzofuranyl, benzothiazolyl, tetrahydrofuranyl, tetrahydropyranyl, piperidinyl, morpholino and pyrrolidinyl.

The term “aromatic group” includes unsaturated cyclic hydrocarbons containing one or more rings. Aromatic groups include 5- and 6-membered single-ring groups which may include from zero to four heteroatoms, for example, benzene, pyrrole, furan, thiophene, imidazole, oxazole, thiazole, triazole, pyrazole, pyridine, pyrazine, pyridazine and pyrimidine, and the like. The aromatic ring may be substituted at one or more ring positions with, for example, a halogen, a lower alkyl, a lower alkenyl, a lower alkoxy, a lower alkylthio, a lower alkylamino, a lower alkylcarboxyl, a nitro, a hydroxyl, —CF₃, —CN, or the like.

The term “alkyl” includes saturated aliphatic groups, including straight-chain alkyl groups, branched-chain alkyl groups, cycloalkyl (alicyclic) groups, alkyl substituted cycloalkyl groups, and cycloalkyl substituted alkyl groups. In preferred embodiments, a straight chain or branched chain alkyl has 20 or fewer carbon atoms in its backbone (e.g., C₁-C₂₀ for straight chain, C₃-C₂₀ for branched chain), and more preferably 12 or fewer. Likewise, preferred cycloalkyls have from 4-10 carbon atoms in their ring structure, and more preferably have 4-7 carbon atoms in the ring structure. The term “lower alkyl” refers to alkyl groups having from 1 to 6 carbons in the chain, and to cycloalkyls having from 3 to 6 carbons in the ring structure.

Moreover, the term “alkyl” (including “lower alkyl”) as used throughout the specification and claims includes both “unsubstituted alkyls” and “substituted alkyls”, the latter of which refers to alkyl moieties having substituents replacing a hydrogen on one or more carbons of the hydrocarbon backbone. Such substituents can include, for example, halogen, hydroxyl, alkylcarbonyloxy, arylcarbonyloxy, alkoxycarbonyloxy, aryloxycarbonyloxy, carboxylate, alkylcarbonyl, alkoxycarbonyl, aminocarbonyl, alkylthiocarbonyl, alkoxyl, phosphate, phosphonato, phosphinato, cyano, amino (including alkyl amino, dialkylamino, arylamino, diarylamino, and alkylarylamino), acylamino (including alkylcarbonylamino, arylcarbonylamino, carbamoyl and ureido), amidino, imino, sulfhydryl, alkylthio, arylthio, thiocarboxylate, sulfate, sulfonato, sulfamoyl, sulfonamido, nitro, trifluoromethyl, cyano, azido, heterocyclyl, aralkyl, or an aromatic or heteroaromatic moiety. It will be understood by those skilled in the art that the moieties substituted on the hydrocarbon chain can themselves be substituted, if appropriate. Cycloalkyls can be further substituted, e.g., with the substituents described above. An “aralkyl” moiety is an alkyl substituted with an aryl, e.g., having 1 to 3 separate or fused rings and from 6 to about 18 carbon ring atoms, (e.g., phenylmethyl (benzyl)).

The term “alkylamino” as used herein means an alkyl group, as defined herein, having an amino group attached thereto. Suitable alkylamino groups include groups having 1 to about 12 carbon atoms, preferably from 1 to about 6 carbon atoms. The term “alkylthio” refers to an alkyl group, as defined above, having a sulfhydryl group attached thereto. Suitable alkylthio groups include groups having 1 to about 12 carbon atoms, preferably from 1 to about 6 carbon atoms. The term “alkylcarboxyl” as used herein means an alkyl group, as defined above, having a carboxyl group attached thereto. The term “alkoxy” as used herein means an alkyl group, as defined above, having an oxygen atom attached thereto. Representative alkoxy groups include groups having 1 to about 12 carbon atoms, preferably 1 to about 6 carbon atoms, e.g., methoxy, ethoxy, propoxy, tert-butoxy and the like. The terms “alkenyl” and “alkynyl” refer to unsaturated aliphatic groups analogous to alkyls, but which contain at least one double or triple bond respectively. Suitable alkenyl and alkynyl groups include groups having 2 to about 12 carbon atoms, preferably from 1 to about 6 carbon atoms.

The term “aryl” includes 5- and 6-membered single-ring aromatic groups that may include from zero to four heteroatoms, for example, unsubstituted or substituted benzene, pyrrole, furan, thiophene, imidazole, oxazole, thiazole, triazole, pyrazole, pyridine, pyrazine, pyridazine and pyrimidine, and the like. Aryl groups also include polycyclic fused aromatic groups such as naphthyl, quinolyl, indolyl, and the like. The aromatic ring can be substituted at one or more ring positions with such substituents, e.g., as described above for alkyl groups. Suitable aryl groups include unsubstituted and substituted phenyl groups. The term “aryloxy” as used herein means an aryl group, as defined above, having an oxygen atom attached thereto. The term “aralkoxy” as used herein means an aralkyl group, as defined above, having an oxygen atom attached thereto. Suitable aralkoxy groups have 1 to 3 separate or fused rings and from 6 to about 18 carbon ring atoms, e.g., O-benzyl.

The term “amino,” as used herein, refers to an unsubstituted or substituted moiety of the formula —NRₐR_{b}, in which Rₐ and R_{b} are each independently hydrogen, alkyl, aryl, or heterocyclyl, or Rₐ and R_{b}, taken together with the nitrogen atom to which they are attached, form a cyclic moiety having from 3 to 8 atoms in the ring. Thus, the term “amino” includes cyclic amino moieties such as piperidinyl or pyrrolidinyl groups, unless otherwise stated. An “amino-substituted amino group” refers to an amino group in which at least one of Rₐ and R_{b}, is further substituted with an amino group.

The term “amino acid” as used herein, refers to a moiety containing an amino group and a carboxylic acid group. The term “amino acid” as used herein, may more specifically refer to a member of a group of 20 natural molecules of the formula HNR_{d}—CRₑR_{f}—COOH, in which R_{d}, Rₑ and R_{f} are each independently hydrogen, alkyl, aryl or heterocyclyl, substituted or unsubstituted, or R_{d} and R_{f} taken together, with the carbon to which R_{f} is attached and the nitrogen to which R_{d} is attached, form a cyclic moiety having three to eight atoms in the ring.

The term “peptide” as used herein, refers to a polymeric chain of two or more amino acids, each linked by an amide group represented by the formula —COONRₐ—, where Rₐ refers to hydrogen or any possible side-chain. A peptide may also include a number of modifications, including phosphorylation, lipidation, prenylation, sulfation, hydroxylation, acetylation, addition of carbohydrate, addition of prosthetic groups or cofactors, formation of disulfide bonds, proteolysis, assembly into macromolecular complexes and the like.

The term “protein” as used herein, refers to a polymeric chain of peptides. A protein may also include a number of modifications, including phosphorylation, lipidation, prenylation, sulfation, hydroxylation, acetylation, addition of carbohydrate, addition of prosthetic groups or cofactors, formation of disulfide bonds, proteolysis, assembly into macromolecular complexes and the like. The term “nucleic acid” as used herein, refers to a polymer made up of nucleotides, themselves made up of a heterocyclic base, a sugar and a phosphate ester.

The term “carbohydrate” refers to an organic molecule containing carbon, hydrogen and oxygen, usually with the empirical formula CH₂O, such as starches or sugars.

The term “cation exchanger” as used herein, refers to an unreactive, organic or inorganic, polymer resin having an acidic residue substituted into the matrix. The term “anion exchanger” as used herein, refers to an unreactive, organic or inorganic, polymer resin having a basic residue substituted into the matrix.

The term “leaving group” as used herein, refers to a group capable of being displaced from a molecule when said molecule undergoes a substitution or elimination reaction.

### SUMMARY OF THE INVENTION

Embodiments of the present invention are directed to a substrate for performing MALDI or DIOS, methods particularly well suited to performing such MALDI or DIOS and methods of making such substrates. The invention described is a device for the presentation of aqueous samples comprising a semiconductor wafer body having at least one first surface and at least one second surface. The first surface is chemically modified to repel an aqueous sample toward the second surface.

One embodiment directed to a substrate for performing MALDI comprises a semiconductor wafer body having at least one first surface. The first surface has a composition as described below:

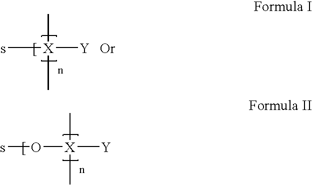

X may represent silicon or germanium or gallium or arsenic and Y may represent a hydroxyl group or hydrogen or a further group, Z, between 5 mol % and 50 mol % of Y being Z. Z may represent —O—WR₁R₂R₃, wherein W is silicon or germanium or carbon, groups R₁, R₂ and R₃ are selected from the groups consisting of C₁ to C₂₅ straight, cyclic or branched alkyl, alkene, aryl, alkoxyl, hydroxyl or siloxyl group, where the group R₁, R₂ and R₃ is unsubstituted or substituted, fully or partially with one or more moieties such as halogen, cyano, amino, diol, nitro, ether, carbonyl, epoxide, sulfonyl, cation exchanger, anion exchanger, carbamate, amide, urea, peptide, protein, carbohydrate or nucleic acid functionalities, where the letter “n” represents the repetition of the above structure across said surface and the letter “s” represents silicon or germanium or gallium or arsenic atoms of said semiconductor wafer, wherein said first surface exhibits a low affinity to aqueous solutions for repelling such solutions.

In a further aspect of the invention, said substrate has at least one second surface for receiving sample. The second surface has a greater affinity for aqueous solutions than the first surface. Preferably, the semiconductor body has a planar face where a plurality of sample receiving second surfaces are arranged in a pattern on the planar face and are surrounded by at least one first surface. The second surface acts to direct an aqueous sample solution to at least one second surface to be ionised.

In another aspect of the invention, a method of making a substrate for presentation of samples for analysis is described. Such a method comprises the steps of:

(i) Providing a semiconductor body having a planar face, the planar face having at least one first surface comprising of a hydride of silicon or germanium or gallium or arsenic on the substrate.
(ii) Reacting at least 5 mol % of the hydride with oxygen to form an oxide of silicon or germanium or gallium or arsenic.
(iii) Reacting the resultant oxide with a compound as shown below

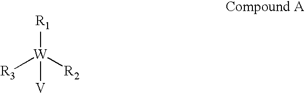

Where V is a halogen, methoxy or any good leaving group, W is silicon or germanium or carbon, groups R₁, R₂ and R₃ consist of C₁ to C₂₅ straight, cyclic or branched alkyl, alkene, aryl, alkoxyl, hydroxyl or siloxyl group and are unsubstituted or substituted, fully or partially with one or more moieties such as halogen, cyano, amino, diol, nitro, ether, carbonyl, epoxide, sulfonyl, cation exchanger, anion exchanger, carbamate, amide, urea, peptide, protein, carbohydrate or nucleic acid functionalities. The reaction is performed such that between 5 mol % and 50 mol % of said surface has structure Z, demonstrated below

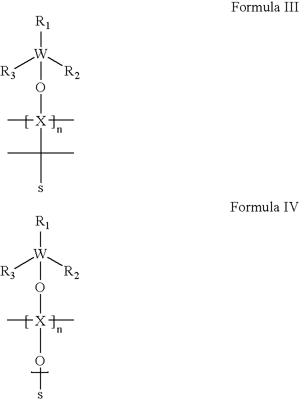

Where X is silicon or germanium or gallium or arsenic and where the letter “n” represents the repetition of the above structure across said surface and the letter “s” represents silicon or germanium or gallium or arsenic atoms of said semiconductor wafer. The resultant first surface exhibits low affinity to aqueous solutions.

In a further aspect of the method, there is made at least one second surface exhibiting greater affinity to aqueous solutions than said first surface, the second surface for concentrating said aqueous solution. Such a second surface may be made by destroying at least one portion of said first surface. The first surface may be destroyed to make the second surface by such methods as laser ablation, heat treatment or reaction with a chemical or enzyme. The second surface may be further oxidised by reaction with oxygen or ozone.

In another aspect of the invention, a method of mass spectrometry is provided, comprising:

(i) Depositing at least one droplet of at least one sample onto a semiconductor wafer having a planar face, said planar face having a first surface having a composition as described below;

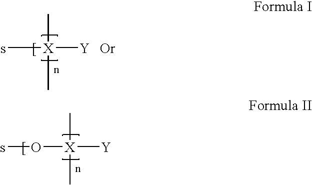

Where X is silicon or germanium or gallium or arsenic and Y may be a hydroxyl group or hydrogen or Z, between 5 mol % and 50 mol % of Y being Z.

The group Z may be represented by the formula —O—WR₁R₂R₃, wherein W is silicon or germanium or carbon. The groups R₁, R₂ and R₃ are selected from the group consisting of C₁ to C₂₅ straight, cyclic or branched alkyl, alkene, aryl, alkoxyl, hydroxyl or siloxyl group, where the groups R₁, R₂ and R₃ are unsubstituted or substituted, fully or partially with one or more moieties such as halogen, cyano, amino, diol, nitro, ether, carbonyl, epoxide, sulfonyl, cation exchanger, anion exchanger, carbamate, amide, urea, peptide, protein, carbohydrate or nucleic acid functionalities.

where the letter “n” represents the repetition of the above structure across said surface and the letter “s” represents silicon or germanium or gallium or arsenic atoms of the semiconductor wafer.

The first surface exhibits a low affinity to aqueous solutions for repelling such solutions and said second surface exhibits a higher affinity to aqueous solutions than said first surface.

(ii) Irradiating said at least one sample droplet to create sample ions,
(iii) Analysing sample ions by mass spectrometry.

In a further aspect of the invention, sample solutions are deposited onto at least one second surface for receiving a sample.

These and other features and advantages will be apparent from viewing the Figures and reading the Detailed Description of the Invention, which follow.

### BRIEF DESCRIPTION OF THE FIGURES

FIG. 1 shows a substrate for performing MALDI.

FIG. 2 shows a mass spectrometer equipped with a laser, capable of performing MALDI.

### DETAILED DESCRIPTION OF THE INVENTION

The present invention will be described in detail as a substrate for performing MALDI or DIOS, methods for performing such MALDI or DIOS and methods of making substrates. Embodiments of the present invention will be described with respect to a system in which a sample is ionised and vaporised for use in a mass analyser. However, those skilled in the art will recognise that the present invention has utility for all applications in which a sample is ionised and vaporised.

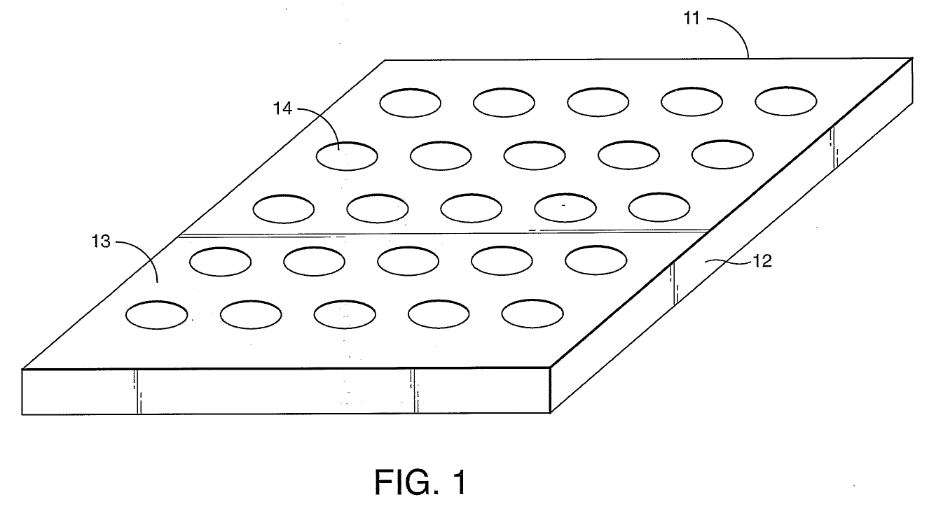

In reference to FIG. 1, substrate 12 has a planar face 11. The substrate is usually rectangular or square in shape, having dimensions of approximately three to four centimetres in length, four to five centimetres in width and one half millimetre in depth. These dimensions and the shape are not critical to the working of the invention, but reflect current manufacturing and application preferences. It is common to make such substrates 11 with dimensions to cooperate with holders and other laboratory devices.

The planar face 11 of substrate 12 has a first surface 13 for directing a sample towards a plurality of second surfaces 14. One embodiment of the present invention is directed to the composition and working of the first surface 13, and further the composition and workings of the second surface 14.

Substrate 12 is fashioned from a semiconductor such as germanium or gallium arsenide, or more preferably silicon. The first surface 13 has a composition represented by the formula:

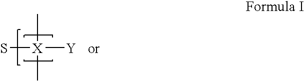

X may represent silicon or germanium or gallium or arsenic and Y may represent a hydroxyl group or hydrogen or a further group, Z, between 5 mol % and 50 mol % of Y being Z. Z may represent the group —O—WR₁R₂R₃, wherein W is silicon or germanium or carbon. The groups R₁, R₂ and R₃ are selected from the group consisting of C₁ to C₂₅ straight, cyclic or branched alkyl, alkene, aryl, alkoxyl, hydroxyl or siloxyl group, where the groups R₁, R₂ and R₃ are unsubstituted or substituted, fully or partially with one or more moieties such as halogen, cyano, amino, diol, nitro, ether, carbonyl, epoxide, sulfonyl, cation exchanger, anion exchanger, carbamate, amide, urea, peptide, protein, carbohydrate or nucleic acid functionalities.

More preferably, Z has the formula —O—WR₁R₂R₃, wherein W is silicon, where the group R₁ consists of a C₅ to C₂₀ straight alkyl chain which may be unsubstituted or substituted, fully or partially with fluorine, and where the groups R₂ and R₃ consist of unsubstituted methyl or ethyl groups.

Most preferably, Z has the formula —O—WR₁R₂R₃, wherein W is silicon, where the group R₁ consists of a C₅ to C₁₇ straight alkyl chain, unsubstituted at C₁ to C₂ and fully substituted with fluorine at C₃ to Cₘ, where m represents an integer from 1 to 17, and where the groups R₂ and R₃ consist of unsubstituted methyl groups.

Most preferably, the mol % of Y being Z is 30 mol % to 40 mol %.

The first surface 13 has a low affinity for aqueous solutions.

The composition of the plurality of second surfaces 14 differs from that of the first surface 13. The mol % of Z on the second surfaces 14 may be less than 5 mol %.

More preferably, the mol % of Z on the second surfaces 14 may be less than 1 mol %.

More preferably, the mol % of Z on the second surfaces 14 may be less than 0.1 mol %.

Most preferably, the mol % of Z on the second surfaces 14 may be 0 mol %.

Preferably, the second surfaces 14 have a composition as described below:

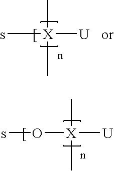

where U represents hydroxyl or hydrogen, the letter “n” represents the repetition of the above structure across said surface and the letter “s” represents silicon or germanium or gallium or arsenic atoms of said semiconductor wafer.

The chemical composition of the first surface 13 and the second surfaces 14 may be such that the second surfaces 14 have a higher affinity to water or aqueous solutions than does the first surface 13. The plurality of second surfaces 14 may be arranged in a pattern on the planar face 11 of the substrate 12 and completely surrounded by the first surface 13, such that the first surface 13 directs an aqueous sample solution onto the second surfaces 14.

A further embodiment of the invention is directed to a method of making a substrate for performing MALDI ionisation. The method comprises the steps of providing a semiconductor body having a planar face. The planar face has at least one first surface comprising a hydride of germanium or gallium or arsenic, or most preferably a hydride of silicon. At least 5 mol % of the hydride is reacted with oxygen, preferably in a reactive form such as ozone, to form an oxide of silicon or germanium or gallium or arsenic. The resultant oxide may be further reacted with a compound as shown below:

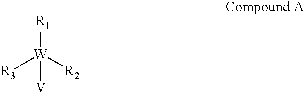

Where V is a halogen, methoxy or any good leaving group, and W is silicon or germanium or carbon. The groups R₁, R₂ and R₃ are selected from the group consisting of C₁ to C₂₅ straight, cyclic or branched alkyl, alkene, aryl, alkoxyl, hydroxyl or siloxyl group, where the groups R₁, R₂ and R₃ are unsubstituted or substituted, fully or partially with one or more moieties such as halogen, cyano, amino, diol, nitro, ether, carbonyl, epoxide, sulfonyl, cation exchanger, anion exchanger, carbamate, amide, urea, peptide, protein, carbohydrate or nucleic acid functionalities. The reaction is performed such that between 5 mol % and 50 mol % of said surface has a structure demonstrated below:

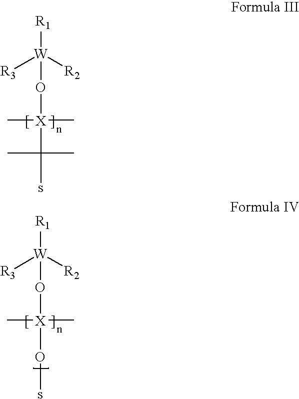

Where X is silicon or germanium or gallium or arsenic and where the letter “n” represents the repetition of the above structure across said surface and the letter “s” represents silicon or germanium or gallium or arsenic atoms of the semiconductor wafer.

More preferably, the components of Compound A are such that W is silicon, the group R₁ consists of a C₅ to C₂₀ straight alkyl chain which may be unsubstituted or substituted, fully or partially with fluorine, and the groups R₂ and R₃ consist of methyl or ethyl groups.

Most preferably, the components of Compound A are such that W is silicon, where the group R₁ consists of a C₅ to C₁₇ straight alkyl chain, unsubstituted at C₁ to C₂ and fully substituted with fluorine at C₃ to Cₘ, where m represents an integer from 1 to 17, and where the groups R₂ and R₃ consist of unsubstituted methyl groups.

In a further aspect of the invention, at least one second surface 14 for receiving a sample is made, the second surface 14 exhibiting a higher affinity to water or aqueous solutions than the said first surface, such that the second surface concentrates aqueous solutions. The second surface may be created by destroying at least one portion of the first surface, by including but not limited to such means as laser ablation, heat treatment or treatment with a chemical or enzyme. More preferably, the second surface is created by laser ablation of the first surface.

More preferably, a plurality of second surfaces for receiving a plurality of samples are made, the plurality of second surfaces exhibiting a higher affinity to water or aqueous solutions than the said first surface, such that the plurality of second surfaces concentrate aqueous solutions. The plurality of second surfaces may be created by destroying a plurality of portions of the first surface, by including but not limited to such means as laser ablation, heat treatment or treatment with a chemical or enzyme. More preferably, the plurality of second surfaces is created by laser ablation of the first surface.

In a further step, the created second surface or plurality of second surfaces may be oxidised, preferably by reaction with oxygen in a reactive state such as ozone.

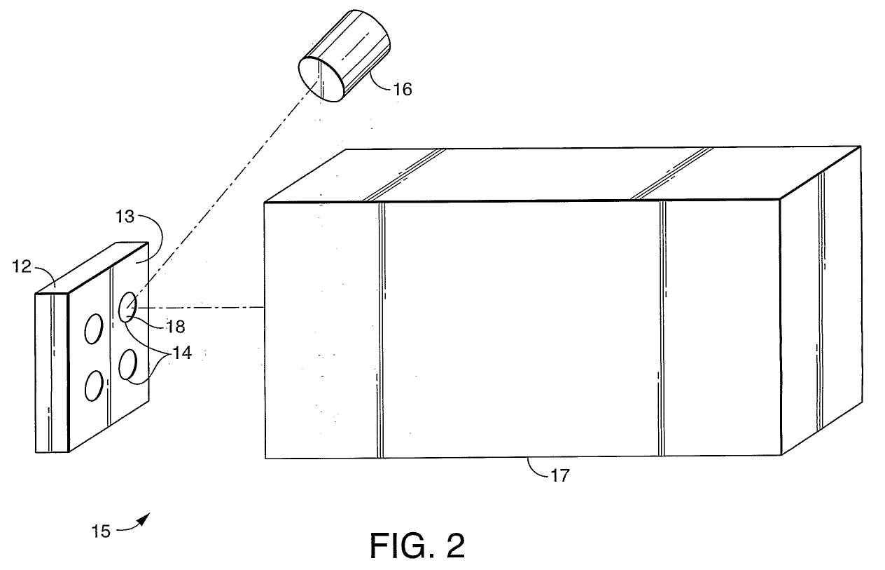

Another embodiment of the invention is directed towards a method for performing MALDI ionization. With reference to FIG. 2, a complete apparatus for performing MALDI analysis 15 is provided. In such an apparatus, a substrate 12 is held in alignment with a laser 16 and in close proximity to the inlet of a mass spectrometer 17. As previously described, the substrate 12 has a first surface 13 and at least one second surface 14. The second surface 14 has a greater affinity to water and aqueous solutions than the first surface 13, owing to the surface chemistries as also previously described.

A sample 18 is placed on the first surface 13 and is drawn away to a second surface 14 by hydrophobic and hydrophilic interactions between the sample 18 and the first surface 13 and second surface 14, respectively. Laser 16 is pulsed, such that the sample 18 is irradiated. More preferably, a sample 18 is placed on a portion of the second surface 14, together with a matrix compound, and laser 16 is pulsed, such that the sample 18 is irradiated. A portion of the sample 18 may be vaporized and ionized. Vapor ions and gases are drawn into the inlet of the mass spectrometer 17, including but not limited to a time-of-flight mass analyser, quadrupole mass analyser, ion cyclotron resonance mass analyser, ion trap mass analyser, fourier transform mass analyser, orbitrap mass analyser or a magnetic sector mass analyser, for analysis. Mass spectrometer 17 provides mass and charge information, such as the mass-to-charge ratio, about the ions received.

Alternatively, a sample 18 is placed on the second surface 14 and is held to the second surface 14 by hydrophobic and hydrophilic interactions between the sample 18 and the first surface 13 and second surface 14, respectively. Laser 16 is pulsed, such that the sample 18 is irradiated. More preferably, a sample 18 is placed on a portion of the second surface 14, together with a matrix compound, and laser 16 is pulsed, such that the sample 18 is irradiated. A portion of the sample 18 may be vaporized and ionized. Vapor ions and gases are drawn into the inlet of the mass spectrometer 17, including but not limited to a time-of-flight mass analyser, quadrupole mass analyser, ion cyclotron resonance mass analyser, ion trap mass analyser, fourier transform mass analyser, orbitrap mass analyser or a magnetic sector mass analyser, for analysis. Mass spectrometer 17 provides mass and charge information, such as the mass-to-charge ratio, about the ions received.

### EXAMPLE 1

### Substrate Surface Modification and MALDI Analysis

A diced silicon chip. 1.4″×2.1″. 0.008-0.2 Ω-cm (Sb-doped), n-type, <100> orientation, was obtained from Silicon Quest International, Inc. (Santa Clara, Calif.). The surface of the chip was rinsed with ethanol. dried, and then oxidized by briefly exposing to a stream of ozone (flow rate of 0.5 g/h from an ozone generator directed at the surface for 30 seconds). The silylation reaction was performed by adding 15 μL of neat (tridecafluoro-I, 1,2,2.tetrahydrooctyl)dimethylchlorosilane on the oxidized chip, placing the chip in a glass Petri dish, and incubating in an oven at 65° C. for 15 minutes. The modified chip was then rinsed thoroughly with methanol and was dried in a stream of N₂.

A 90 W CO₂ laser equipped with X,Y & Z micrometer adjustments and video visual imaging was used to remove the covalently attached silane from the surface of the MALDI target. After positioning the substrate in front of the laser, the laser was then pulsed briefly to ablate the surface. The substrate was then re-exposed briefly to a stream of ozone in order to ensure that the surface-ablated regions were hydrophilic.

1 μL of a sample containing 100 attomole/μL of [Glu^{I}]-Fibrinopeptide B (GluFib) (SigmaAldrich, St. Louis, Mo.) dissolved in 75/25 water/acetonitrile with 0.1%. TFA was spotted onto one of the ablated spots, and then allowed to dry at room temperature. Then 1 μL of 0.035 mg/mL α-cyano-4-hydroxycinnamic acid (CHCA) (Waters Corp.) dissolved in 75/10/15 acetonitrile/ethanol/aqueous 0.1% TFA was spotted onto the target and allowed to dry at room temperature. The target plate was placed in the MALDI instrument for analysis in reflectron mode. 100 laser pulses were made (10 scans, 10 shots/scan). The resulting spectrum exhibited an excellent signal to noise ratio.

### EXAMPLE 2

### Tryptic Digest

A diced and ablated silicon chip was prepared in the same manner as described in Example 1. 1 μL of a sample containing 100 attomole/μL of yeast alcohol dehydrogenase tryptic digest (Waters Corp.) dissolved in 75/25 water/acetonitrile, 0.1% TFA was spotted onto one of the ablated spots, and then allowed to dry at room temperature. Then 1 μL of 0.035 mg/mL CHCA dissolved in 75/10/15 acetonitrile/ethanol/aqueous 0.1% TFA was spotted onto the target and allowed to dry at room temperature. The target plate was placed in the MALDI instrument for analysis in reflectron mode. 100 laser pulses were made (10 scans, 10 shots/scan). The resulting spectrum is shown in FIG. 4.

Thus while preferred embodiments of the invention have been described, those skilled in the art will recognize that the present invention is subject to modification and alteration. Therefore, the invention should not be limited the precise details in the detailed description and the Figures, but should include such subject matter encompassed by the following claims and their equivalents.

1. A device for the presentation of samples for analysis comprising, a semiconductor wafer body having at least one first surface and at least one second surface, said first surface having a composition as described below; 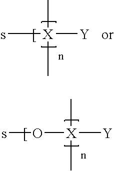
where X is silicon or germanium or gallium or arsenic and Y is hydrogen or hydroxyl or Z, between 5 mol % and 50 mol % of Y being Z,
where Z is —O—WR₁R₂R₃, wherein W is silicon germanium or carbon, groups R₁, R₂ and R₃ are selected from the group consisting of C₁ to C₂₅ straight, cyclic or branched alkyl, alkene, aryl, alkoxyl, hydroxyl or siloxyl group, where the groups R₁, R₂ and R₃ are unsubstituted or substituted, fully or partially with one or more moieties such as halogen, cyano, amino, diol, nitro, ether, carbonyl, epoxide, sulfonyl, cation exchanger, anion exchanger, carbamate, amide, urea, peptide, protein, carbohydrate or nucleic acid functionalities,
where the letter “n” represents the repetition of the above structure across said surface and the letter “s” represents silicon or germanium or gallium or arsenic atoms of said semiconductor wafer,
wherein said first surface exhibits a low affinity to aqueous solutions for repelling such solutions, and said second surface exhibits a higher affinity to aqueous solutions than said first surface.

2. The device of claim 1 where said mol % of Y being Z is 30-40 mol %.

3. The device of claim 1 where said R₁ group is partially or fully substituted with fluorine.

4. The device of claim 1 where said R₁ group consists of a C₅ to C₁₇ straight alkyl group.

5. The device of claim 4 where said R₁ group is partially or fully substituted with fluorine.

6. The device of claim 5 where said R₁ group is unsubstituted at C₁ to C₂ and fully substituted at C₃ to Cₘ, where m represents an integer from 1 to 17.

7. The device of claim 6 where said groups R₂ and R₃ are short alkyl chains.

8. The device of claim 7 where said groups R₂ and R₃ are methyl groups.

9. The device of claim 8 where said groups R₂ and R₃ are unsubstituted.

10. The device of claim 9 wherein said body has a planar face having at least one said first surface and at least one said second surface, said first surface directing said aqueous solution on said second surface to be ionised.

11. The device of claim 1 comprising a plurality of said at least one second surface in which each second surface is surrounded by at least one first surface.

12. The device of claim 11 where in said plurality of said second surfaces is arranged in a pattern on said body.

13. The device of claim 1 where the mol % of Z on at least one of said second surface is less than 5%.

14. The device of claim 13 where the mol % of Z on at least one of said second surface is less than 1%.

15. The device of claim 14 where the mol % of Z on at least one of said second surface is less than 0.1%.

16. The device of claim 1 where said at least one second surface has a surface described below; 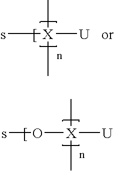
where U represents hydroxyl or hydrogen, and where the letter “n” represents the repetition of the above structure across said surface and the letter “s” represents silicon or germanium or gallium or arsenic atoms of said semiconductor wafer.

17. The device of claim 16 where said mol % of Y being Z is 30-40 mol %.

18. The device of claim 16 where said R₁ group is partially or fully substituted with fluorine.

19. The device of claim 18 where said R₁ group consists of a C₅ to C₁₇ straight alkyl group.

20. The device of claim 19 where said R₁ group is partially or fully substituted with fluorine.

21. The device of claim 20 where said R₁ group is unsubstituted at C₁ to C₂ and fully substituted at C₃ to Cₘ, where m represents an integer from 1 to 17.

22. The device of claim 18 where said groups R₂ and R₃ are short alkyl chains.

23. The device of claim 22 where said groups R₂ and R₃ are methyl groups.

24. The device of claim 23 where said groups R₂ and R₃ are unsubstituted.

25. The device of claim 24 wherein said body has a planar face having at least one said first surface and at least one said second surface, said first surface directing said aqueous solution on said second surface to be ionised.

26. The device of claim 25 comprising a plurality of said at least one second surface in which each second surface is surrounded by at least one first surface.

27. The device of claim 26 where in said plurality of said second surfaces is arranged in a pattern on said body.

28. A method of making a substrate for presentation of samples for analysis, comprising the steps of
(i) providing a semiconductor body having a planar face, said planar face having at least one first surface comprising of a hydride of silicon or germanium or gallium or arsenic on said substrate,
(ii) reacting at least 5 mol % of said hydride with oxygen to form an oxide of silicon or germanium or gallium or arsenic,
(iii) reacting the resultant oxide with a compound as shown below 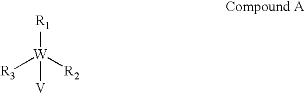
where V is a halogen, methoxy or any good leaving group, W is silicon or germanium or carbon, R₁, R₂ and R₃ consist of a C₁ to C₂₅ straight, cyclic or branched alkyl, alkene, aryl, alkoxyl, hydroxyl or siloxyl group and are unsubstituted or substituted, fully or partially with one or more moieties such as halogen, cyano, amino, diol, nitro, ether, carbonyl, epoxide, sulfonyl, cation exchanger, anion exchanger, carbamate, amide, urea, peptide, protein, carbohydrate or nucleic acid functionalities, such that between 5 mol % and 50 mol % of said surface has structure Z, demonstrated below 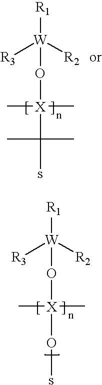
where X is silicon or germanium or gallium or arsenic, where the letter “n” represents the repetition of the above structure across said surface and the letter “s” represents silicon or germanium or gallium or arsenic atoms of said semiconductor wafer, and;
wherein said first surface exhibits low affinity to aqueous solutions,
(iv) creating at least one second surface on said planar face by destruction or partial destruction of said first surface, wherein said second surface has a higher affinity to aqueous solutions than said first surface.

29. The method of claim 28 where said R₁ group is partially or fully substituted with fluorine.

30. The method of claim 29 where said R₁ group consists of a C₅ to C₁₇ straight alkyl group.

31. The method of claim 30 where said R₁ group is unsubstituted at C₁ to C₂ and fully substituted at C₃ to Cₘ, where m represents an integer from 1 to 17.

32. The method of claim 31 where said groups R₂ and R₃ are short alkyl chains.

33. The method of claim 32 where said groups R₂ and R₃ are methyl groups.

34. The method of claim 33 where said groups R₂ and R₃ are unsubstituted.

35. The method of claim 28 wherein said at least one second surface is further oxidised.

36. The method of claim 28 wherein said at least one second surface is further reacted with oxygen in the form of ozone.

37. The method of claim 28 where said at least one second surface is formed by laser ablation.

38. The method of claim 28 where said at least one second surface is formed by heat treatment.

39. The method of claim 28 where said at least one second surface is formed by treatment with a chemical or enzyme.

40. The method of claim 28 wherein a plurality of said at least one second surfaces are made in which each said second surface is surrounded by at least one first surface.

41. The method of claim 40 wherein said plurality of said at least one second surfaces is arranged in a pattern on said planar face of said body.

42. The method of claim 41 where said R₁ group is partially or fully substituted with fluorine.

43. The method of claim 42 where said R₁ group consists of a C₅ to C₁₇ straight alkyl group.

44. The method of claim 43 where said R₁ group is unsubstituted at C₁ to C₂ and fully substituted at C₃ to Cₘ, where m represents an integer from 1 to 17.

45. The method of claim 44 where said groups R₂ and R₃ are short alkyl chains.

46. The method of claim 45 where said groups R₂ and R₃ are methyl groups.

47. The method of claim 46 where said groups R₂ and R₃ are unsubstituted.

48. A method of mass spectrometry comprising,
(i) depositing at least one droplet of at least one sample onto a semiconductor wafer having a planar face, said planar face having at least one first surface and at least one second surface, said first surface having a composition as described below; 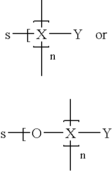
where X is silicon or germanium or gallium or arsenic and Y is hydrogen or hydroxyl or Z, between 5 mol % and 50 mol % of Y being Z,
where Z is —O—WR₁R₂R₃, wherein W is silicon germanium or carbon, groups R₁, R₂ and R₃ are selected from the group consisting of C₁ to C₂₅ straight, cyclic or branched alkyl, alkene, aryl, alkoxyl, hydroxyl or siloxyl group, where the groups R₁, R₂ and R₃ are unsubstituted or substituted, fully or partially with one or more moieties such as halogen, cyano, amino, diol, nitro, ether, carbonyl, epoxide, sulfonyl, cation exchanger, anion exchanger, carbamate, amide, urea, peptide, protein, carbohydrate or nucleic acid functionalities,
where the letter “n” represents the repetition of the above structure across said surface and the letter “s” represents silicon or germanium or gallium or arsenic atoms of said semiconductor wafer,
wherein said first surface exhibits a low affinity to aqueous solutions for repelling such solutions, and said second surface exhibits a higher affinity to aqueous solutions than said first surface,
(ii) irradiating said at least one sample droplet to create sample ions,
(iii) analysing said sample ions by mass spectrometry.

49. The method of claim 48 where said at least one droplet is deposited onto said second surface.

50. The method of claim 48 where said at least one droplet is deposited onto said first surface, said first surface directing said droplet toward said second surface.

51. The method of claim 50 where said ions are analysed by a time-of-flight mass analyser, quadrupole mass analyser, ion cyclotron resonance mass analyser, ion trap mass analyser, fourier transform mass analyser, orbitrap mass analyser or a magnetic sector mass analyser.

52. A device for the presentation of aqueous samples comprising, a semiconductor wafer body having at least one first surface and at least one second surface, said first surface being chemically modified to repel said aqueous sample toward said second surface.
